(19) United States
(12) Patent Application Publication
(10) Pub. No.: US 2006/0013041 A1
(43) Pub. Date: Jan. 19, 2006

(54) Nonvolatile memory structure with high speed high bandwidth and low voltage

(76) Inventor: Chin-Hsi Lin, Hsinchu (TW)

Correspondence Address: J C PATENTS, INC., 4 VENTURE, SUITE 250, IRVINE, CA, 92618, US

(21) Appl. No.: 11/233,917

(22) Filed: Sep. 23, 2005

Related U.S. Application Data
(63) Continuation of application No. 10/510,079, filed on Sep. 30, 2004.

(30) Foreign Application Priority Data
Apr. 28, 2003 (WO) PCT/IB03/01594

(51) Int. Cl. G11C 16/06; G11C 11/34; G11C 16/04

(52) U.S. Cl. 365/185.05; 365/185.11; 365/185.2

(57) ABSTRACT

The invention is directed to a via-mask read only memory (ROM) layout structure, including a dynamic random access memory (DRAM) like layout structure, serving as a main body structure and having an array of coding transistors. A grounding structure line is disposed over the source regions of the coding transistors. The grounding layer is located at a position, where capacitor areas are defined in a DRAM structure. A plurality of vias are corresponding to a portion of the coding transistors, for coupling the source regions with the grounding structure line. Each of the vias in the corresponding coding transistors represents a first binary data, and the coding transistors without the vias represent a second binary data.

### CROSS-REFERENCE TO RELATED APPLICATION

This application is a continuation application of, and claims the priority benefit of, U.S. application Ser. No. 10/510,079 filed on Sep. 30, 2004.

### BACKGROUND OF THE INVENTION

1. Field of Invention

The present invention relates to semiconductor memory. More particularly, the present invention relates to a memory array layout for a nonvolatile memory, such as flash memory implemented with double-ended sense amplifier to have higher operation speed.

2. Description of Related Art

Memory devices are typically provided as internal storage areas in the computer. The term memory identifies data storage that comes in the form of integrated circuit chips. In general, memory devices contain an array of memory cells for storing data, and row and column decoder circuits coupled to the array of memory cells for accessing the array of memory cells in response to an external address.

There are several different types of memory. One type is RAM (random-access memory). This is typically used as main memory in a computer environment. RAM refers to read and write memory; that is, you can repeatedly write data into RAM and read data from RAM. This is in contrast to ROM (read-only memory), which generally only permits the user in routine operation to read data already stored on the ROM. Most RAM is volatile, which means that it requires a steady flow of electricity to maintain its contents. As soon as the power is turned off, whatever data was in RAM is lost.

Computers almost always contain a small amount of ROM that holds instructions for starting up the computer. Unlike RAM, ROM generally cannot be written to in routine operation. An EEPROM (electrically erasable programmable read-only memory) is a special type of non-volatile ROM that can be erased by exposing it to an electrical charge. Like other types of ROM, EEPROM is traditionally not as fast as RAM. EEPROM comprise a large number of memory cells having electrically isolated gates (floating gates). Data is stored in the memory cells in the form of charge on the floating gates. Charge is transported to or removed from the floating gates by programming and erase operations, respectively.

Yet another type of non-volatile memory is a Flash memory. A Flash memory is a type of EEPROM that can be erased and reprogrammed. Many modern PCs have their. BIOS stored on a flash memory chip so that it can easily be updated if necessary. Such a BIOS is sometimes called a flash BIOS. Flash memory is also popular in modems because it enables the modern manufacturer to support new protocols as they become standardized.

A typical Flash memory comprises a memory array that includes a large number of memory cells arranged in row and column fashion. Each of the memory cells includes a floating gate field-effect transistor capable of holding a charge. The cells are usually grouped into blocks. Each of the cells within a block can be electrically programmed in a random basis by charging the floating gate. The charge can be removed from the floating gate by a block erase operation. The data in a cell is determined by the presence or absence of the charge in the floating gate.

As memory sizes continue to increase, satisfying the demands for high-speed access of memory arrays becomes increasingly difficult. Increasing memory sizes have been made possible in large part by continuing advances in semiconductor fabrication, i.e., placing more transistors and interconnect lines in the same die area. However, reduced dimensions of transistors leads to lower drive while reduced dimensions of interconnect lines leads to increased resistance. Managing this reduced drive and higher resistance through array organization thus becomes an important factor in providing high-speed access in high-performance memory devices.

Memory development always follows requests of PC or related devices. Even hierarchy memory systems are adopted in currently system design, the low-level memories, like DRAM, also need high speed and high bandwidth to reduce the barrier between processors. Based on that, the development of DRAM is able to represent the basic track of memory developing. Now, synchronous DRAM is the main stream, then DDR and QDR. The nonvolatile memories are also expected to be the trend, in which the SMROM (synchronous Mask ROM) has been used in some devices, like printers. Also and, flash memory, as the promising product of nonvolatile memories, had been developed as synchronous application by Micron Technology, whose spec. is compatible to SDRAM. Other manufacturer also proposes the synchronous spec., but its spec. is little different from SDRAM.

Comparing various types between currently used nonvolatile memory and sync. DRAM (SDRAM), the latency spec. is the main difference. For example, SyncFlash developed by Micron technology had the latency 2-3-8 (Row latency-Col. Latency-Burst Length, respectively), not fully compatible to 2-2-8 of SDRAM spec. already used now. FIG. 2 shows the relation.

The main difference is due to the array structure. Of course, the difference results from the different characteristics of memory cells. Double-end sensing scheme is adopted on DRAM. And small-size sense amplifier can suit into the width of memory cell column. Single-ended sensing is commonly used in nonvolatile memory design, and reliability concerns on the drain voltage that makes sense amplifier necessarily to be large area. FIGS. 1A-1B show the architecture difference owing to the basic characteristics of 2 kinds of memory cells.

FIG. 1A is the DRAM architecture and FIG. 1B is the nonvolatile memory (NVM). The memory array usually is arranged into rows (word lines) and columns (bit lines) driven by the row drive circuit 102 and the column drive circuit 106. In DRAM operation, the column address is sensed by the sense amplifier 104 and is decoded. In NVM operation, the column address is selected and sensed. The sense amplifier in the conventional NVM conventionally is the type of single-ended sense amplifier 116. The reasons are following. Within a memory IC, sense amplifiers are used to read data from a target memory cell within a memory array. These amplifiers are typically categorized as single-ended sense amplifiers or differential sense amplifier. Single-ended sense amplifiers are commonly used in memories having a single-bit per memory cell. Examples of single-bit per cell memories are EEPROM and Flash EPROMs. These single-bit per cell memories store only one of the true value or compliment value of a datum item in each memory cell. This is in contrast to dual-bit per cell memories such as SRAMs, which store both the true and complement value of a datum item in each memory cell. Having both the true and complement value of a datum item within each memory cell facilitates and speeds up the reading of a memory cell since one can identify the stored datum item by simultaneously accessing both true and complement bits and simply determining which has the higher voltage potential. Stated more clearly, SRAMs use differential amplifiers to read each memory cell, and identify the logic state stored within a memory cell as soon as the direction of the voltage imbalance, representative of the true and complimentary data stored within the memory cell, is determined. Since single-bit per cell memories do not have the luxury of knowing the compliment of the stored datum item, their single-ended sensing circuitry requires a different and more critically balanced approach.

Use of a differential sense amplifier in a nonvolatile memory would provide a big boost in reading speed, but would require two memory storage devices per memory cell, one for the true data and another for the complement data. This would reduce the memory capacity at least by 50%. It is more likely that the reduction would be much greater because of the need to accommodate additional bit lines, equalization circuitry, more complex program and erase circuitry, and other circuitry required to implement a dual-bit per memory cell architecture. Therefore, conventional nonvolatile memories generally use single-ended sense amplifiers.

Designing synchronous product with the current structure will increase the latency cycles compared SDRAM products. FIG. 2 shows the latency quantities for the DRAM-like and the conventional NVM structure. FIG. 3 shows the cell layout for the conventional NVM in more details. Above schematics clearly show the differences between the 2 structures. Because the synchronous specification has the address multiplexers to get low pin counts, DRAM-like structure may be more suitable in applications.

### SUMMARY OF THE INVENTION

The invention provides a nonvolatile memory structure, which can be operated in high speed, high bandwidth and low voltage.

The invention provides a nonvolatile memory structure which is based on the typical DRAM memory cell structure and modify the DRAM memory cell structure into a MASK ROM memory cell structure.

As embodied and broadly described herein, the invention provides a via-mask read only memory (ROM) layout structure, including a dynamic random access memory (DRAM) like layout structure, serving as a main body structure and having an array of coding transistors. A grounding structure line is disposed over the source regions of the coding transistors. The grounding layer is located at a position, where capacitor areas are defined in a DRAM structure. A plurality of vias are corresponding to a portion of the coding transistors, for coupling the source regions with the grounding structure line. Each of the vias in the corresponding coding transistors represents a first binary data, and the coding transistors without the vias represent a second binary data.

The invention also provides a memory array bank structure for a nonvolatile memory, which comprises: a plurality of memory cell transistors are arranged in a matrix form by a plurality of rows and a plurality of columns. Wherein, the rows are corresponding to word lines and two adjacent columns are grouped into a dual-cell column with respect to one bit line. The bit line is branched, for example, into a first branch bit line selected by a first selection signal and a second branch bit line selected by a second selection signal. Here, two branch bit lines are used as the example for descriptions. The actual number of the branch lines for grouping the columns can be set as the design choice. Wherein, the first branch bit line connects all drain electrodes at one side of the dual-cell column and the second branch bit line connects all drain electrodes at the other side of the dual-cell column, and one common source line connected all source electrodes of the dual-cell column. A selection reference row of transistors with respect to the dual-cell columns is coupled to the world line as a reference world line, such as the last world line, wherein gate electrodes of the transistors in the selection reference row are coupled to a selection reference signal. A first source/drain electrode of the transistors is coupled to the first branch bit line, and a second source/drain electrode of the transistors is coupled to the common source line of the next dual-cell column. Also and, a plurality of selection transistors coupled to the dual-cell columns at the common source lines, respectively, in which a bank selection signal can be fed.

In the foregoing memory array bank structure, the transistors of the selection reference row has a relatively large channel length.

The invention also provides a memory array bank structure for a nonvolatile memory, which comprises a number of first column of memory cells coupled in cascade to form a first column, having a first end side and a second end side. A number of second column of memory cells are coupled in cascade to form a second column, having a first end side and a second end side, wherein the first column and the second column are arranged to has a plurality of rows indicated as word lines. A first selection transistor is coupled in series with the first end side of the first column of memory cells. A second selection transistor is coupled in series with the first end side of the second column of memory cells. A bit line has a first branch bit line and a second branch bit line, respectively coupled to the first column and the second column via the first selection transistor and the second selection transistor. A word line reference cell row of reference cell transistors, wherein the reference cell transistors are respectively coupled to the first column and the second column at the second ends in series. Wherein the open ends of the first branch bit line and the second branch bit line are coupled to a double-ended sense amplifier.

The present invention also provides a cell layout for a nonvolatile memory, which comprises a first memory bank, which has a bank selection transistor row at one side and a reference cell row at the other side. Wherein, two adjacent columns are grouped into one sector with two bit lines, and rows are arranged to be word lines. A second memory bank has a bank selection transistor row at one side and a reference cell row at the other side. Wherein, two adjacent columns are grouped into one sector with two bit lines and rows are arranged to be word lines, and the bit lines of the first memory bank and the second memory bank are correspondingly connected together. Also and, the first memory bank and the second memory bank are coupled at the sides having the bank selection transistor row. A plurality of double-ended sense amplifiers by each are implemented between the two adjacent bit lines.

In the foregoing nonvolatile memory, each of the reference cell transistors has large channel length.

The present invention also provides a cell layout for a nonvolatile memory, which comprise a first memory bank, having a bank selection transistor row at one side and a reference cell row at the other side. Wherein, two adjacent columns are grouped into one sector with two bit lines, and rows are arranged to be word lines. A second memory bank has a bank selection transistor row at one side and a reference cell row at the other side, wherein two adjacent columns are grouped into one sector with two bit lines and rows are arranged to be word lines. The bit lines of the first memory bank and the second memory bank are correspondingly connected together, as well as the first memory bank and the second memory bank are coupled at the sides having the bank selection transistor row. A plurality of double-ended sense amplifiers by each is implemented between the two adjacent bit lines.

The present invention provides a cell layout for a nonvolatile memory, which comprises a first memory bank, having a bank selection transistor row at one side and a reference cell row at the other side. Wherein, two adjacent columns are grouped into one sector with two branch bit lines, the two branch bit lines are combined into one bit line in the bank selection transistor row, and rows are arranged to be word lines. A second memory bank has a bank selection transistor row at one side and a reference cell row at the other side, in which two adjacent columns are grouped into one sector with two branch bit lines. The two branch bit lines are combined into one bit line in the bank selection transistor row and rows are arranged to be word lines. A plurality of double-ended sense amplifiers, wherein each one of the sense amplifier is implemented to receive the two bit lines respectively from the first memory bank and the second memory bank.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a drawing, schematically illustrating a conventional DRAM device architecture.

FIG. 1B is a drawing, schematically illustrating a conventional nonvolatile memory device architecture.

FIG. 2 is a time consumption in operation for DRAM-like structure and a conventional NVM structure.

FIG. 3 is a circuit diagram, schematically a conventional NVM device.

FIGS. 4A-4B are drawings, schematically illustrating the memory structure with the double-ended sense amplifiers, according to a preferred embodiment of the invention.

FIG. 5 is a circuit drawing schematically illustrating the structure of memory-cell bank with one dedicated reference-cell row based on AND-type flash memory, according to one preferred embodiment of this invention.

FIG. 6 is a circuit diagram, schematically illustrating a double-ended sense amplifier used in the present invention.

FIG. 7 is a waveform of internal signal and control signals for a latch sense amplifier.

FIG. 8 is a circuit drawing schematically illustrating the structure of memory-cell bank with one dedicated reference-cell row based on NOR-type or DiNOR flash memory, according to one preferred embodiment of this invention.

FIG. 9 is a drawing, schematically illustrating the architecture of mask ROM layout based on the DRAM fabrication process, according to one preferred embodiment of this invention.

FIG. 10 is a drawing, schematically illustrating the equivalent circuit of the mask ROM in FIG. 9, according to one preferred embodiment of this invention.

FIGS. 11-15 are drawings, schematically illustrating the circuit architectures for various types of memory device, according to one preferred embodiment of this invention.

### DESCRIPTION OF THE PREFERRED EMBODIMENTS

Synchronous NVM structures are proposed in the invention to get as fast as a SDRAM device, or even as fast as DDR and future synchronous memory devices. It is possible to track with the synchronous application of DRAM to get better performance and matched with system architecture. One dedicated reference row is introduced in one bank array, which is also to create the reference current for another bank, while it is selected. The double-ended sense amplifiers are easy to implement in the invention, an cross-coupled latched type sense amplifier is for example the typical one in which only small layout area is needed to make large synchronous page size possible. Sync. Flash structures are proposed in the invention, based on AND, NOR and DiNOR structure. For ROM applications, popular buried diffusion ROM is modified in the invention to get the targets. Especially, the synchronous ROM based on the modified DRAM process is proposed by easy design in the synchronous market.

In the following description about the invention, only the essential parts to design the memory device are described in detail, but some actual implementations, which should be known by the skilled artisans, to accomplish the memory device are not described. Several examples are provided for better descriptions as follows:

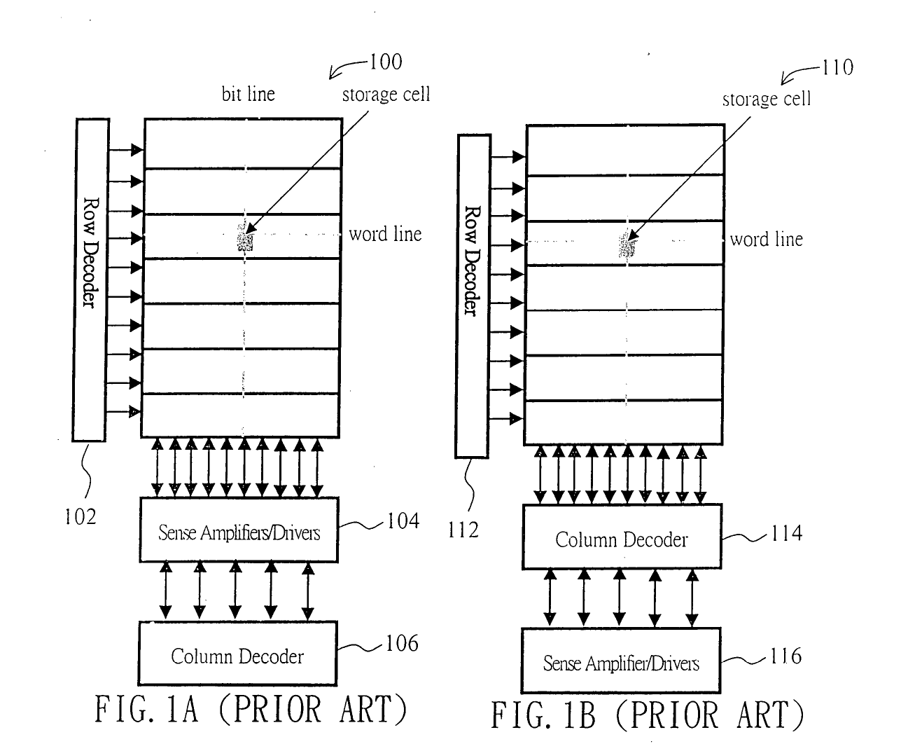

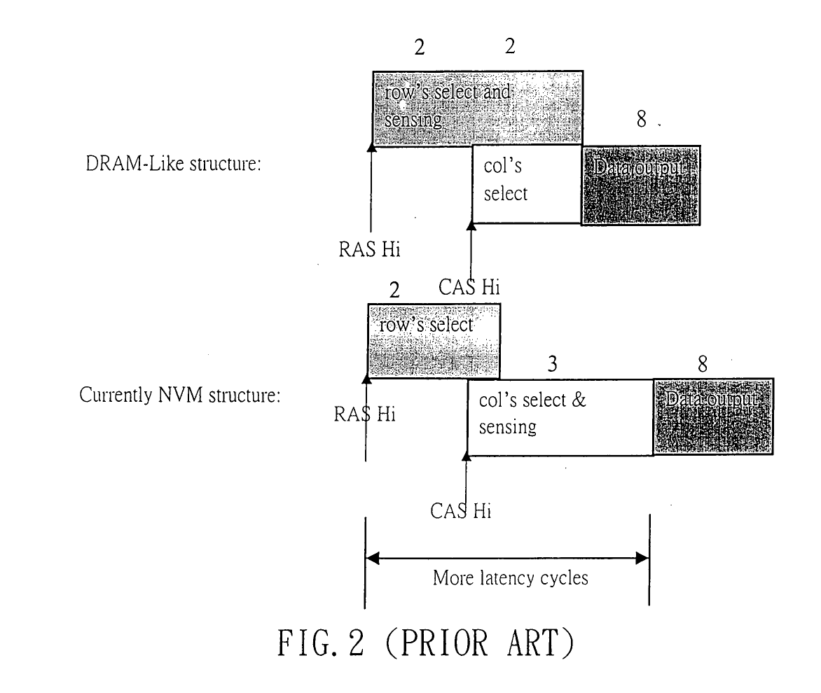

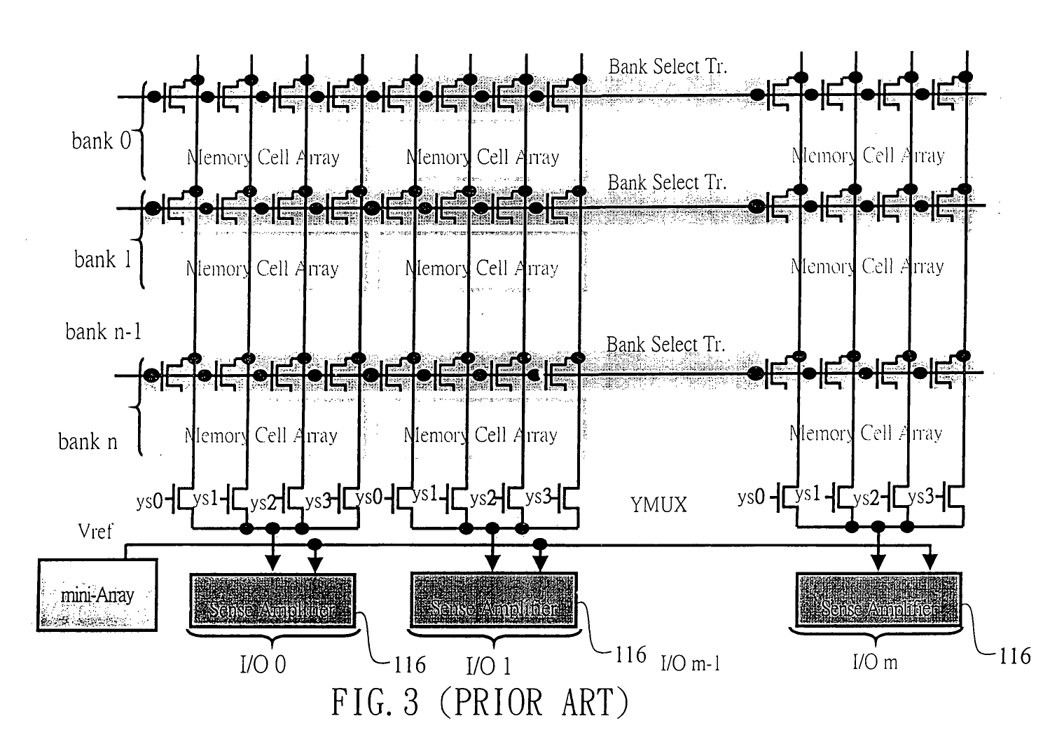

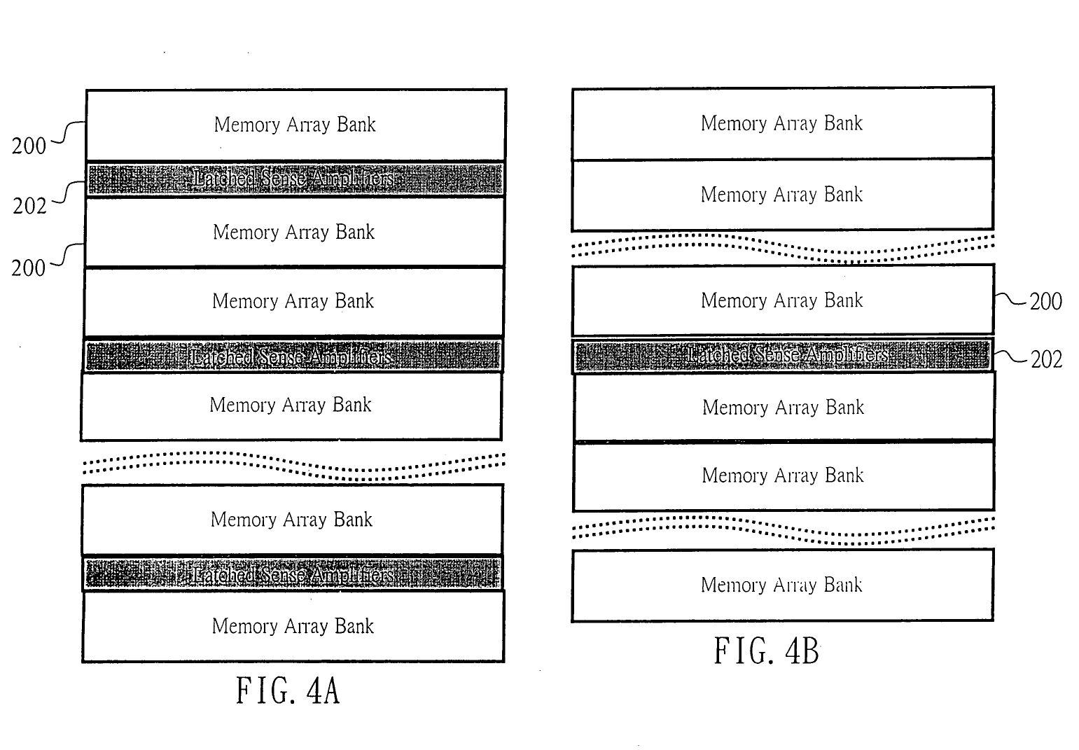

FIGS. 4A-4B are drawings, schematically illustrating the memory structure with the double-ended sense amplifiers, according to a preferred embodiment of the invention. The main design principle of the invention is using the double-ended sense amplifiers, implemented between two memory banks. This is different from the conventional NVM in FIG. 1B and FIG. 3, which are designed by using the single-ended sense amplifiers, resulting in low operation speed.

In FIG. 4A, every two memory banks 200 are implemented with a double-ended sense amplifier 202, such as a latched sense amplifier, there between. Alternatively in FIG. 4B, when a number of the memory banks 200 are grouped into a unit, such as a block or any grouped unit, the two units can be combined with the double-ended sense amplifier 202. The operation mechanism is that two banks of memory cells share one bank sense amplifier. Since row addresses of one bank are decoded, the related charge will be coupled to sense amplifiers and the other bank working as the reference also couples to sense amplifier and develop.

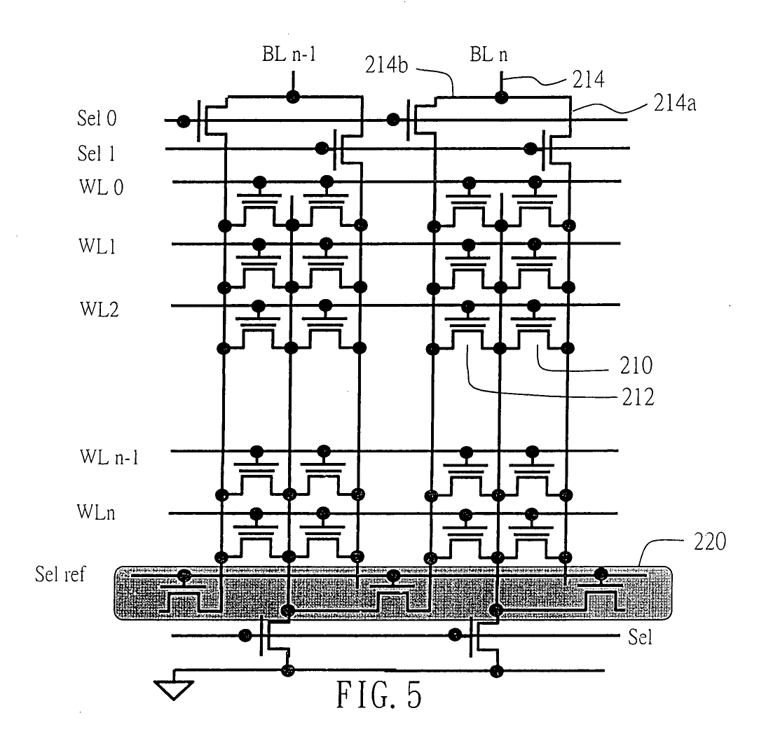

One of schematics of bank array is like the circuit architecture as shown in FIG. 5, in which an AND type flash structure, for example, is presented and added with one row dummy flash cells, called as a reference row 220 of reference cells. Based on that, simplified latched sense amplifiers are used and placed within one column pitch. For example, a plurality of memory cell transistors are arranged in a matrix form by a plurality of rows (controlled by word lines WL#) and a plurality of columns (controlled by the bit lines BL#). The rows are corresponding to word lines and two adjacent columns 210, 212 are grouped into a dual-cell column with respect to one bit line 214. The bit line 214 is branched into a first branch bit line 214a selected by a first selection signal Sel 0 and a second branch bit line 214b selected by a second selection signal Sel 1. Wherein, the first branch bit line 214a connects all drain electrodes at one side of the dual-cell column and the second branch bit line 214b connects all drain electrodes at the other side of the dual-cell column, and one common source line connected all source electrodes of the dual-cell column. A selection reference row 220 of transistors with respect to the dual-cell columns is coupled to the last world line, i.e. WLn, wherein the gate electrodes of the transistors in the selection reference row 220 are coupled to a selection reference signal Sel_ref. A first source/drain electrode of the transistors in BL n is coupled to the first branch bit line 214a, and a second source/drain electrode of the transistors is coupled to the common source line of the next dual-cell column, i.e., BL n-1. Also and, a plurality of selection transistors coupled to the dual-cell columns at the common source lines, respectively, in which a bank selection signal Sel can be fed.

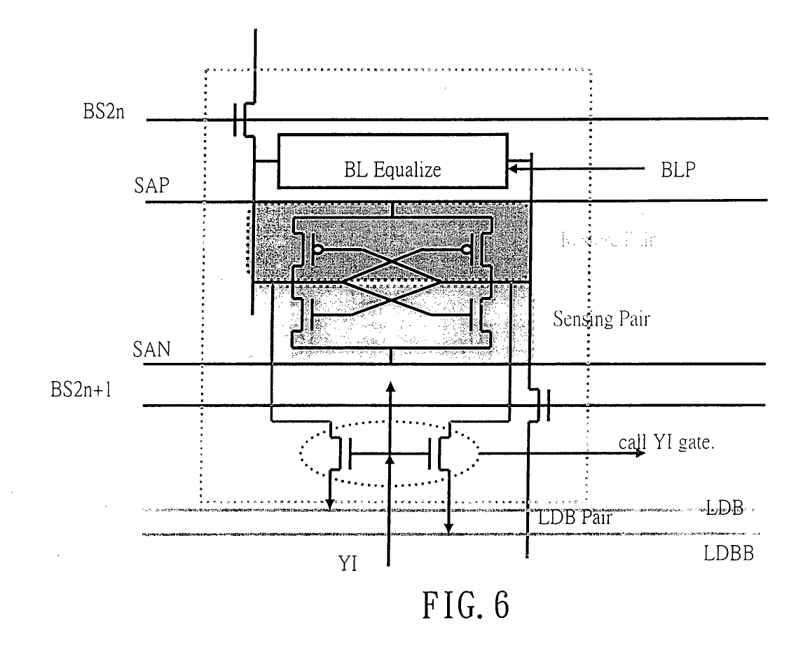

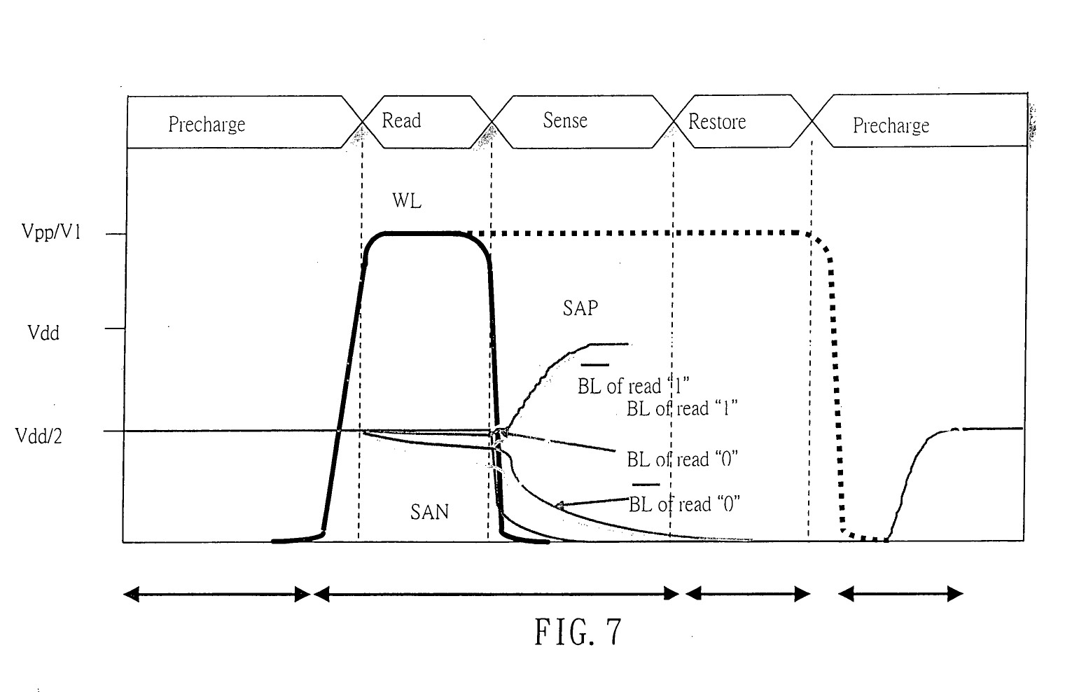

The transistor in the selection reference row 220 has a relatively large channel length. This is used to as a threshold to discern the signal state of “0” or “1” by the double-ended sense amplifier, which is schematically illustrated in FIG. 6. Basically, the capacitor for the storage cell is precharged to a voltage level of Vcc/2. Once the cell is selected, the voltage will be developed and then the content of “0” or “1” can be discerned. FIG. 7 shows the waveform in operation. During word line read stage, due to the reference cells with the long channel length, which cause the different responses for the bit line and the complementary bit line with respect to the different logic states of “0” and “1”. In general, the operating scheme is similar with the DRAM sensing. First stage is to pre-charge BL, BL-Bar and they are equalized. The selected word line and reference word line are coupled to certain voltage. The reference and memory cell current had been build up to discharge the bit line (BL) and bit line bar (or complementary bit line, BL-Bar). The difference between BL and BL-Bar will be developed due to the different reference and cell current level. Then sense amplifier is enabled to further develop signals and latched.

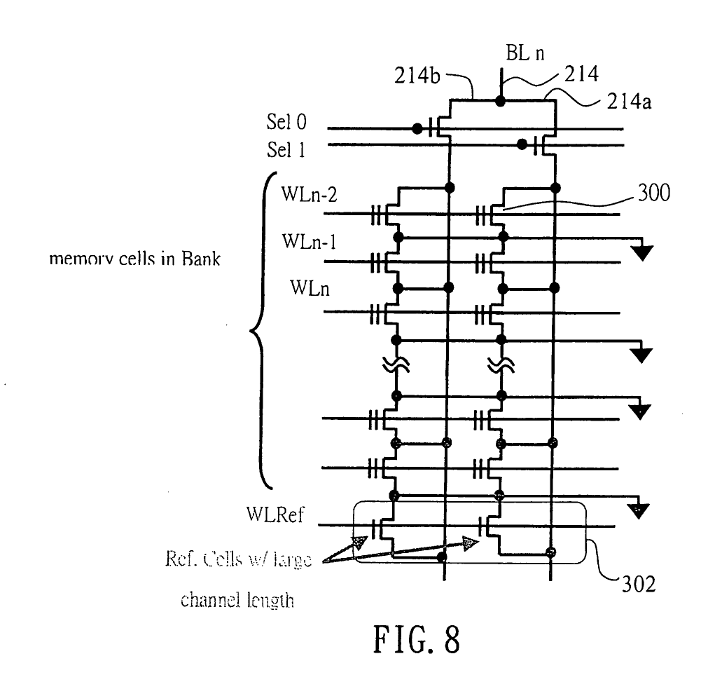

The same design principle can also be applied to other type of NVM. FIG. 8 is a circuit drawing schematically illustrating the structure of memory-cell bank with one dedicated reference-cell row based on NOR-type or DiNOR flash memory, according to one preferred embodiment of this invention. In FIG. 8, the memory cells are arranged in different way from FIG. 5. For example, two columns of memory cells 300, shown by transistors 300, are grouped into a dual-cell column. The memory transistors are coupled in series in each column. Each of the transistors 300 in one column is connected by a branch bit line 214a, while the other column is likewise connected by a branch bit line 214b. The branch bit line 214a and the branch bit line 214b are selected by the selection signals Sel o and Sel 1 via the selection transistors, and are couple to the bit line BLn. The invention particularly introduces a reference row 302 with reference cells, which have relatively large channel length. The reference row 302 as a word line reference is coupled to one end side of the dual-cell column opposite to the selection side. The branch bit lines 212a, 214b are open and can be coupled to the double-ended sense amplifier.

Alternatively, the design principle can also be applied to the read only memory (ROM) device. The mask ROM had been adopted in several applications, and Sync. ROM had used in some fields recently. In order to easily enter the Synchronous memory market, a modified DRAM process in the invention is proposed. Basically, the scheme is similar with the above mentions. There is one reference-cell row dedicated to one bank array.

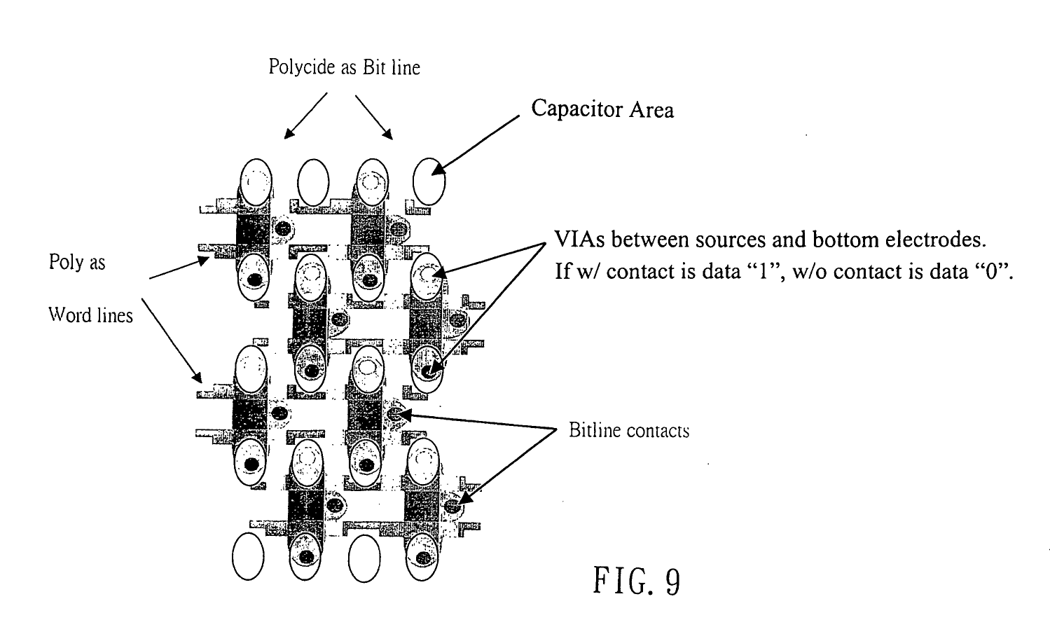

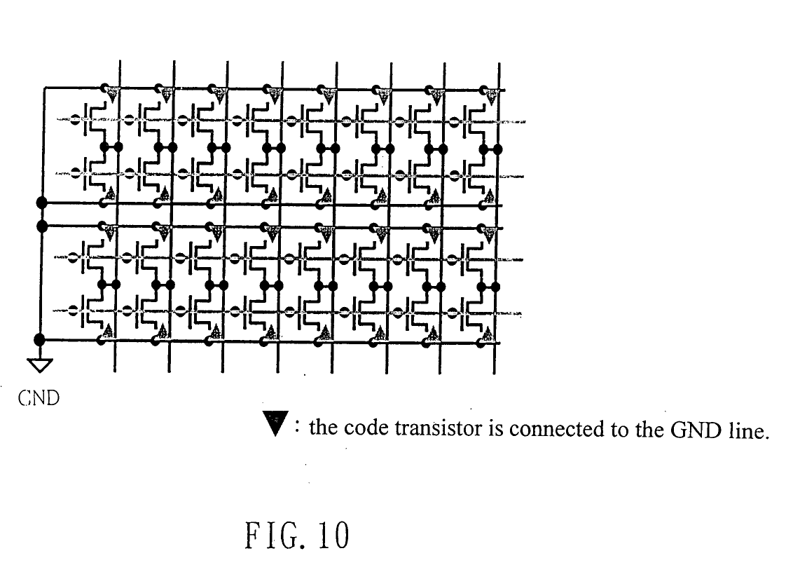

About how to get Mask ROM based on currently DRAM process, the via is used as the data code layer, that is to connect the source side of MOS to bottom electrode of capacitor. The bottom electrode and the top electrode of the capacitor are electrically connected together. In other words, the capacitor function used in DRAM is no longer existing for the Mask ROM of the present invention. However, a grounding structure line is disposed over the source regions of the coding transistors, wherein the grounding layer is located at a position, where the capacitor areas are defined in a DRAM structure. The capacitor areas are now a part of the grounding structure line. The Mask ROM based on currently DRAM process can be achieved. The status of whether or not the via exits in the memory cell is referring to the content of binary data in “0” or “1”. FIGS. 9-10 show the layout of the mask ROM base on the DRAM fabrication process into a VIA-Mask ROM and the related circuit architecture.

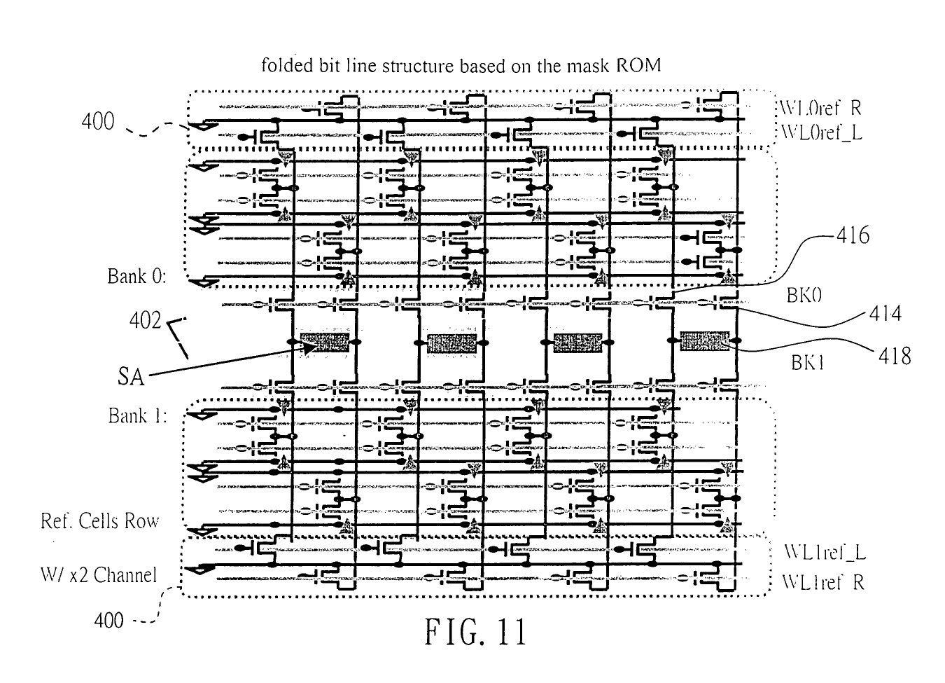

In the invention, by introducing the reference cell rows, several cell layout for the nonvolatile memory devices are provided. For example, a cell layout for a nonvolatile memory in folded bit line is provided as shown in FIG. 11. In FIG. 11, only two memory banks are shown called first memory bank Bank0 and a second memory bank Bank1. The first memory bank (upper one) has a bank selection transistor row 402 at one side and a reference cell row 400 at the other side. Two adjacent columns, with respect to bit lines, are grouped into one group, such as one sector, with two adjacent bit lines 414 and 416, in vertical directions. Here, the bit lines 414 and 416 are complementary to each other. The rows are arranged to be the word lines. Likewise, the second memory bank (lower one) includes a bank selection transistor row 402 at one side and a reference cell row 400 at the other side. Two adjacent columns are also grouped into one sector with two bit lines 414 and 416. Rows are arranged to be word lines in this second memory bank, wherein the bit lines of the first memory bank and the second memory bank are correspondingly connected together. The first memory bank and the second memory bank are coupled at the sides having the bank selection transistor row 402.

A number of double-ended sense amplifiers 418 are implemented between every the two adjacent bit lines 414 and 416. The reference cell row 400 includes transistors with relatively large channel length, such as twice of the usual channel length, but same gate level. The reference cell row 400 are also arranged to have a left word line reference row and a right word line reference row, so as to select the left column or the right column in one dual-cell column.

The double-ended sense amplifiers 418 are implemented between the two adjacent bit lines in one dual-cell column. Therefore the two adjacent memory banks are folded together, and this structure is referred to a folded bit line structure. The via is used to store the binary data.

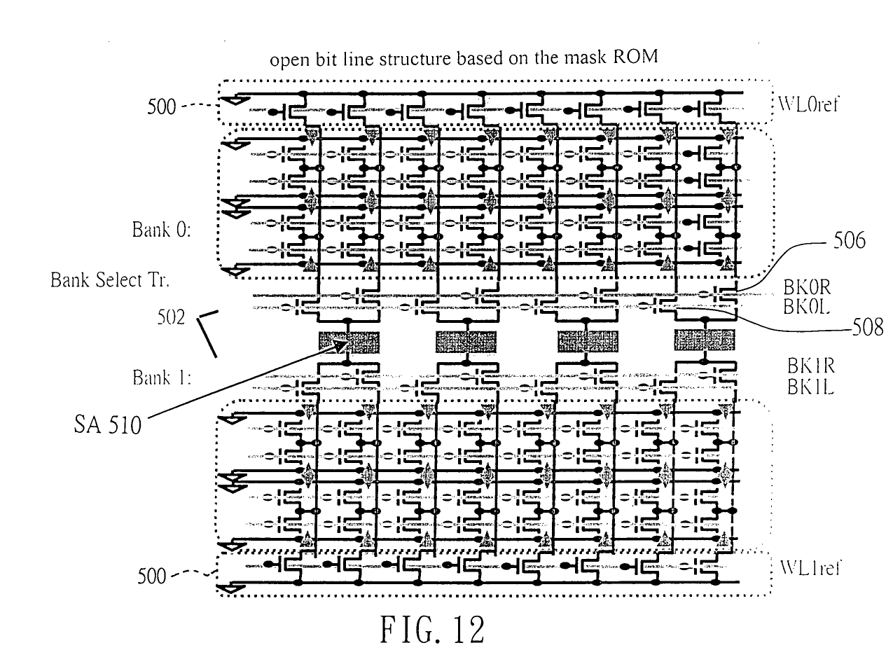

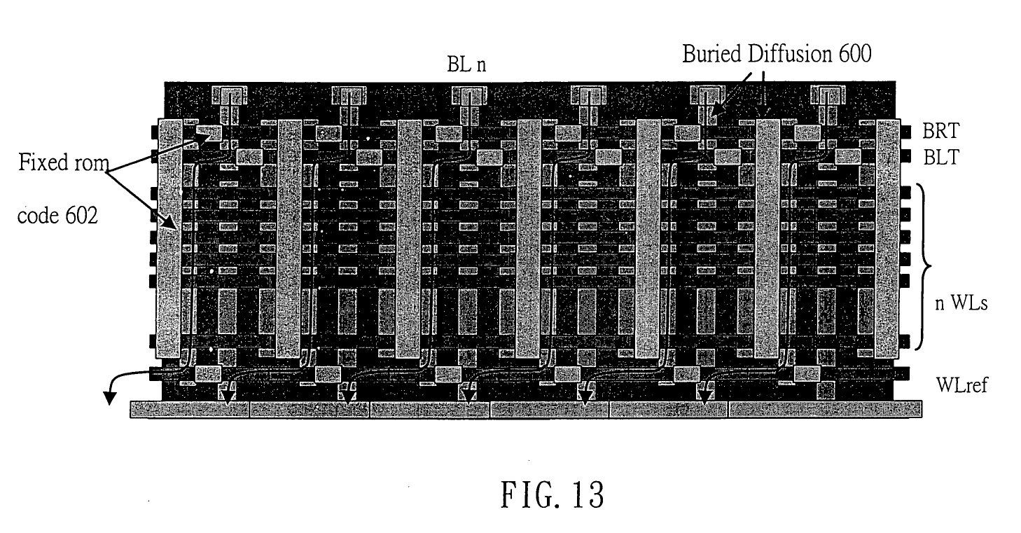

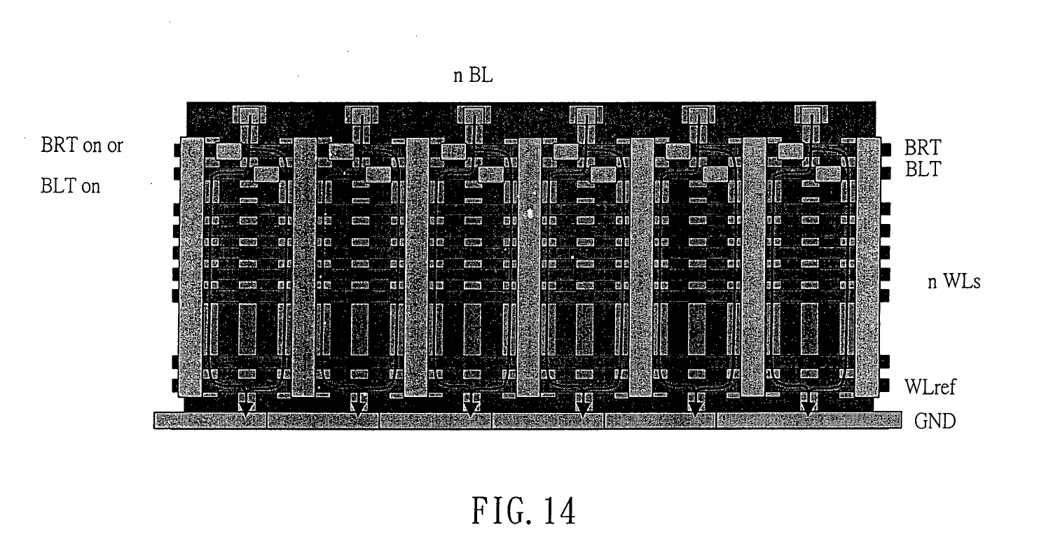

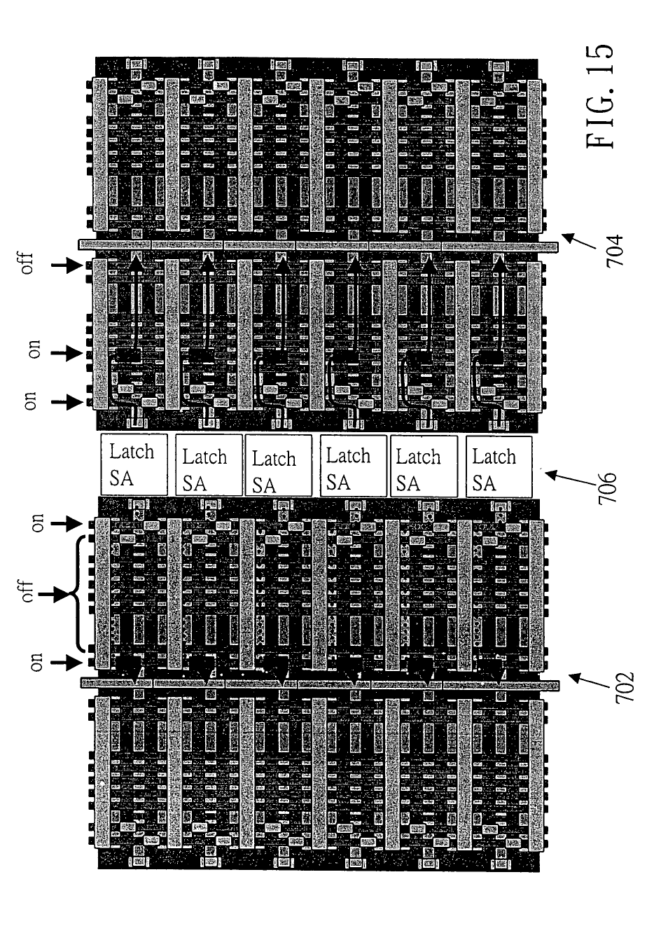

Alternatively, the design with respect to the open bit line structure is also shown in FIG. 12 as an example. In FIG. 12, a cell layout for a nonvolatile memory includes a first memory bank Bank0, having a bank selection transistor row 502 at one side and a reference cell row 500 at the other side. Two adjacent columns are grouped into one sector with two branch bit lines. The two branch bit lines are combined into one bit line in the bank selection transistor row 502. The rows are arranged to be word lines. Likewise, a second memory bank Bank1 includes a bank selection transistor row 502 at one side and a reference cell row 500 at the other side. Two adjacent columns are grouped into one sector with two branch bit lines. The two branch bit lines are combined into one bit line in the bank selection transistor row and rows are arranged to be word lines. In the foregoing bank selection transistor row 502, two transistors 506 and 508 are coupled in series and then combine the two branch bit lines into the single bit line for each one of the memory banks. The two transistors 506 and 508 are used to select the right bank or the left bank. It should be noted that, the transistors 504 in the reference cell row 500 preferably has the larger channel length, such as twice of the regular channel length, and the gate level can be set to be the same. However, the channel can also be set to be the same but with different gate level. This is the design choice.

Two adjacent memory bank are to be coupled together. In this situation, a number of double-ended sense amplifiers 510 arranged as a row corresponding to the bit line, wherein each one of the sense amplifier is implemented to receive the two bit lines respectively from the first memory bank and the second memory bank.

In conclusions, not like the conventional design, the present invention has employing the double-ended sensing amplifier to operate like a DRAM, so that the operation speed, the bandwidth can be improved, and the operation voltage can be lowered. Also and, the memory size cam also be reduced. Furthermore, the additional dummy reference row is included, in which the channel length can be relatively large, such as twice. This is helpful to develop the content of the binary data in the storage cells.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A via-mask read only memory (ROM) layout structure, comprising:
a dynamic random access memory (DRAM) like layout structure, as a main body structure, including an array of coding transistors;
a grounding structure line over source regions of the coding transistors, wherein the grounding layer is located at a position, where capacitor areas are defined in a DRAM structure; and
a plurality of vias with respect to a portion of the coding transistors, for coupling the source regions with the grounding structure line, wherein each of the vias in the corresponding coding transistors represents a first binary data, and the coding transistors without the vias represent a second binary data.

2. The via-mask ROM layout structure of claim 1, wherein the first binary data is “1” and the second binary data is “0”.

3. The via-mask ROM layout structure of claim 1, wherein the first binary data is “0” and the second binary data is “1”.

4. The via-mask ROM layout structure of claim 1, wherein the DRAM like layout structure comprises:
a plurality of first column of memory cells coupled in cascade as a first column, having a first end side and a second end side;
a plurality of second column of memory cells coupled in cascade as a second column, having a first end side and a second end side, wherein the first column and the second column are arranged to has a plurality of rows indicated as word lines;
a first selection transistor coupled in series with the first end side of the first column of memory cells;
a second selection transistor coupled in series with the second end side of the second column of memory cells;
a bit line, which has a first branch bit line and a second branch bit line, respectively coupled to the first column and the second column via the first selection transistor and the second selection transistor; and
a word line reference cell row of reference cell transistors, wherein the reference cell transistors are respectively coupled to the first column and the second column at the second ends in series,
wherein the open ends of the first branch bit line and the second branch bit line are coupled to a double-ended sense amplifier.

5. The via-mask ROM layout structure of claim 1, wherein the DRAM like layout structure comprises:
a first memory bank, having a bank selection transistor row at one side and a reference cell row at the other side, wherein two adjacent columns are grouped into one sector with a bit line and a bar bit line, and rows are arranged to be word lines;
a second memory bank, having a bank selection transistor row at one side and a reference cell row at the other side, wherein two adjacent columns are grouped into one sector with a bit line and a bar bit line, and rows are arranged to be word lines, wherein the bit lines and the bar bit lines of the first memory bank and the second memory bank are correspondingly connected together, as well as the first memory bank and the second memory bank are coupled at the sides having the bank selection transistor row; and
a plurality of double-ended sense amplifiers, wherein each one of the sense amplifier is implemented between the bit line and the bar bit line in the same sector.

6. The via-mask ROM layout structure of claim 1, wherein the DRAM like layout structure comprises:
a first memory bank, having a bank selection transistor row at one side and a reference cell row at the other side, wherein two adjacent columns are grouped into one sector with two branch bit lines, the two branch bit lines are combined into one bit line in the bank selection transistor row and rows are arranged to be word lines;
a second memory bank, having a bank selection transistor row at one side and a reference cell row at the other side, wherein two adjacent columns are grouped into one sector with two branch bit lines, the two branch bit lines are combined into one bit line in the bank selection transistor row and rows are arranged to be word lines; and
a plurality of double-ended sense amplifiers, wherein each one of the sense amplifier is implemented to receive the two bit lines respectively from the first memory bank and the second memory bank.
